(19) United States
(12) Patent Application Publication
(10) Pub. No.: US 2026/0328842 A1
(43) Pub. Date: Oct. 22, 2026

(54) SCAN CHAIN CIRCUIT OF SEMICONDUCTOR INTEGRATED CIRCUIT AND SCAN TEST OPERATION METHOD THEREOF

(71) Applicant: SAMSUNG ELECTRONICS CO., LTD., Suwon-si (KR)

(72) Inventors: Chanho LEE, Suwon-si (KR); Kyuwon CHOI, Suwon-si (KR)

(73) Assignee: SAMSUNG ELECTRONICS CO., LTD., Suwon-si (KR)

(21) Appl. No.: 19/463,682

(22) Filed: Jan. 29, 2026

(30) Foreign Application Priority Data
Apr. 21, 2025 (KR) 10-2025-0051862

(51) Int. Cl. G01R 31/3185

(52) U.S. Cl. CPC G01R 31/318536; G01R 31/318541; G01R 31/318555; G01R 31/318583; G01R 31/318594

(57) ABSTRACT

A scan chain circuit of a semiconductor integrated circuit includes a first scan latch and a second scan latch. The first scan latch is configured to receive a first signal from a combinational logic circuit during a first scan operation and store the first signal in a master latch in response to a first clock signal. The first scan latch is also configured to receive a second signal from the combinational logic circuit during a second scan operation and store the second signal in the master latch in response to the first clock signal. The second scan latch is configured to form a scan chain with the first scan latch, and store a signal provided from the combinational logic circuit in a slave latch in response to a second clock signal.

### CROSS-REFERENCE TO RELATED APPLICATIONS

This application claims priority under 35 U.S.C. § 119 to Korean Patent Application No. 10-2025-0051862 filed on Apr. 21, 2025, in the Korean Intellectual Property Office, the disclosures of which are incorporated by reference herein in their entireties.

### BACKGROUND

Example embodiments of the present disclosure described herein relate to a semiconductor integrated circuit, and more specifically, to a scan chain circuit of a semiconductor integrated circuit and a scan test operation method thereof.

A scan chain circuit includes a plurality of flip-flops that are coupled in series. In the scan chain circuit, an input terminal of each flip-flop is coupled to an output terminal of a previous flip-flop, and an output terminal of each flip-flop is coupled to an input terminal of a next flip-flop. The scan chain circuit is a design for test (DFT) circuit for efficiently testing a semiconductor device, such as an integrated circuit, and may be used in a scan test. Further, the scan chain circuit may be used in utilizing data sensed from an electrical fuse (e-fuse).

The scan test circuit of a semiconductor integrated circuit is used only for the test operation. Therefore, it is desirable to design it with the smallest possible area. However, a large number of flip-flops are used in the scan chain circuit. In addition, multiple latches are used for each flip-flop. However, there is a limit to reducing the number of flip-flops in the scan chain circuit. Therefore, in order to reduce the area of the scan chain circuit, a circuit that can perform the scan test operation while occupying a smaller area is required instead of the flip-flop.

### SUMMARY

Example embodiments of the present disclosure provide a scan chain circuit that may perform a scan test operation using a latch that occupies a smaller area than a flip-flop without using a flip-flop, and a semiconductor integrated circuit including the same.

According to an embodiment, a scan chain circuit of a semiconductor integrated circuit, comprises: a first scan latch configured to receive a first signal from a combinational logic circuit during a first scan operation and store the first signal in a master latch in response to a first clock signal, and receive a second signal from the combinational logic circuit during a second scan operation and store the second signal in the master latch in response to the first clock signal; and a second scan latch configured to form a scan chain with the first scan latch, and store a signal provided from the combinational logic circuit in a slave latch in response to a second clock signal.

According to an embodiment, a semiconductor integrated circuit comprises: a combinational logic circuit configured to generate a first signal and a second signal; a scan chain circuit configured to include a first scan latch that operates in response to a first clock signal and a second scan latch that operates in response to a second clock signal; and a scan controller configured to provide the first clock signal and the second clock signal. Wherein the first scan latch receives the first signal from the combinational logic circuit during a first scan operation and stores it in a master latch in response to the first clock signal, and receives the second signal from the combinational logic circuit during a second scan operation and stores it in the master latch in response to the first clock signal. And wherein the second scan latch forms a scan chain with the first scan latch and stores the signal provided from the combinational logic circuit in a slave latch in response to the second clock signal.

According to an embodiment, a scan test operation method of a semiconductor integrated circuit which includes a combinational logic circuit generating a first signal and a second signal, a scan chain circuit including a first scan latch operating in response to a first clock signal and a second scan latch operating in response to a second clock signal; and a scan controller providing the first clock signal and the second clock signal, comprises: receiving the first signal from the combinational logic circuit during a first scan operation and storing it in a master latch in response to the first clock signal; and receiving the second signal from the combinational logic circuit during a second scan operation and storing it in the master latch in response to the first clock signal.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating an integrated circuit having a scan chain circuit of a semiconductor memory device.

FIG. 2 is a timing diagram illustrating a scan test operation of scan flip-flops included in the scan chain circuit of the integrated circuit of FIG. 1.

FIG. 3 is a block diagram illustrating an example embodiment of the first scan flip-flop of the scan chain circuit illustrated in FIG. 1.

FIG. 4 is a circuit diagram illustrating an example embodiment of the first flip-flop illustrated in FIG. 3.

FIG. 5 is a circuit diagram illustrating an example embodiment of the first three-phase buffer illustrated in FIG. 4.

FIGS. 6, 7 and 8 are block diagrams illustrating a semiconductor integrated circuit having a scan chain circuit according to an embodiment of the present disclosure.

FIG. 9 is a table illustrating an example embodiment of the mode operation of the semiconductor integrated circuit illustrated in FIG. 6.

FIGS. 10 and 11 are circuit diagrams and timing diagrams illustrating an example embodiment of the normal mode of the semiconductor integrated circuit illustrated in FIG. 6.

FIGS. 12 and 13 are circuit diagrams and timing diagrams illustrating an example embodiment of a first scan mode of the semiconductor integrated circuit illustrated in FIG. 6.

FIGS. 14 and 15 are circuit diagrams and timing diagrams illustrating an example embodiment of the second scan mode of the semiconductor integrated circuit illustrated in FIG. 6.

### DETAILED DESCRIPTION

Below, example embodiments of the present disclosure will be described in detail and clearly to such an extent that an ordinary one in the art easily implements the inventive concepts.

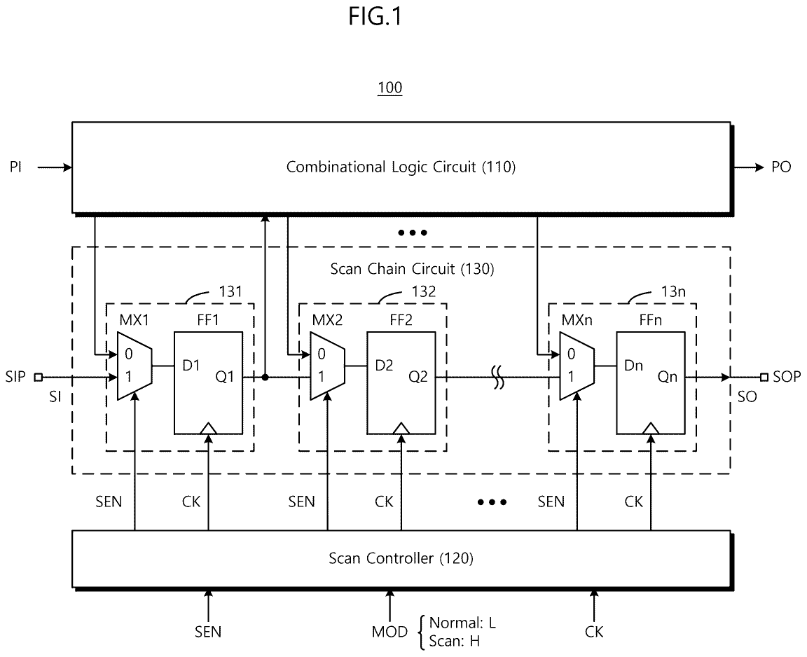

FIG. 1 is a block diagram illustrating an integrated circuit having a scan chain circuit of a semiconductor memory device. Referring to FIG. 1, the integrated circuit 100 may include a combinational logic circuit 110, a scan controller 120, and a scan chain circuit 130. A predetermined test pattern, that is, scan input data (SI; scan-In-Data), may be sequentially input through a scan test input terminal (SIP). And scan output data (SO; scan-Out-Data) stored in the scan chain circuit 130 may be sequentially output through a scan test output terminal (SOP).

In FIG. 1, the combinational logic circuit 110 is illustrated as being connected to the scan chain circuit 130 within the integrated circuit 100, but some combinational logic circuits that do not require scan testing within the integrated circuit 100 may not be connected to the scan chain circuit 130. According to an example embodiment, the integrated circuit 100 may be implemented as a system on-chip (SOC). Scan input data may be sequentially input through one of the main input terminals (PI) of the combinational logic circuit 110. And scan output data stored in the scan chain circuit 130 may be sequentially output through one of the main output terminals (PO) of the combinational logic circuit 110.

The scan controller 120 may receive a scan enable signal (SEN), a scan mode signal (MOD), and a clock signal (CK). The scan controller 120 may provide the received scan enable signal (SEN) to the scan chain circuit 130. The scan controller 120 may receive the scan mode signal (MOD) and perform a scan test operation. For example, if the scan mode signal (MOD) is a logic low level (L), the scan controller 120 may operate in a normal mode, and if the scan mode signal (MOD) is a logic high level (H), the scan controller 120 may operate in a scan mode.

The scan chain circuit 130 may include a plurality of scan flip-flops 131 to 13n. Each scan flip-flop (e.g., 131) may be connected to the combinational logic circuit 110 to form a scan path. Each scan flip-flop may include a multiplexer and a flip-flop. For example, the first scan flip-flop 131 may include a first multiplexer (MX1) and a first flip-flop (FF1). During the scan mode, the first multiplexer (MX1) may perform a shift-in operation, a capture operation, and a shift-out operation in response to the scan enable signal (SEN). During the shift-in operation and the shift-out operation, the <1> selection terminal of the first multiplexer (MX1) may be selected, and during the capture operation, the <0> selection terminal may be selected.

The scan test operation may be a shift-in operation in which a test pattern, that is, scan input data (SI), is sequentially loaded into the scan chain circuit 130. A capture operation may be performed in which observation values of the combinational logic circuit 110 based on loaded scan input data (SI) are stored in the scan chain circuit 130. A shift-out operation may be performed in which the observation values stored in the scan chain circuit 130 are sequentially output as scan output data (SO).

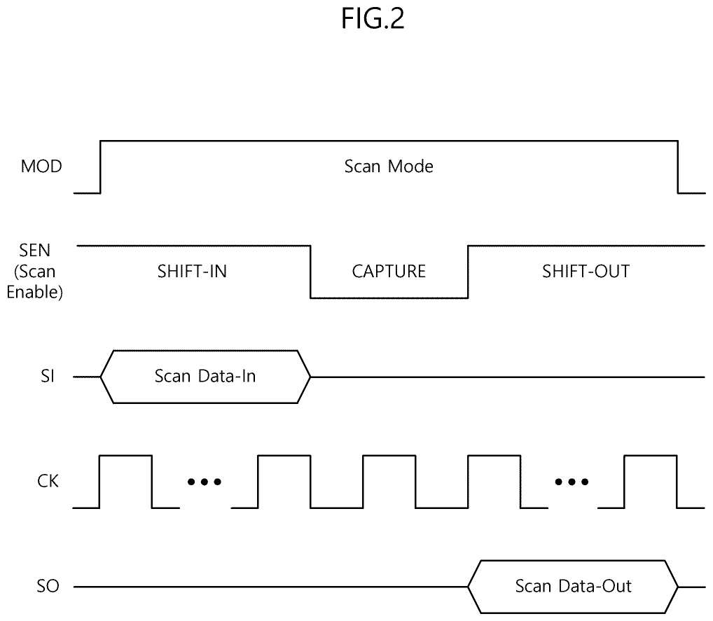

FIG. 2 is a timing diagram illustrating a scan test operation of scan flip-flops included in the scan chain circuit of the integrated circuit of FIG. 1.

Referring to FIGS. 1 and 2, while a scan enable signal (SEN) applied to the integrated circuit 100 may have a logic high level, a shift-in operation may be performed (e.g., indicated as SHIFT-IN) in which a predetermined test pattern, e.g., scan input data (SI), is sequentially input to the scan chain circuit 130 through the scan test input terminal (SIP) of the integrated circuit 100.

A capture operation may be performed (e.g., indicated as CAPTURE) in which observation values of the combinational logic circuit 110 based on the scan input data (SI) loaded into the scan chain circuit 130 is stored in the scan chain circuit 130. At this time, the scan enable signal (SEN) applied to the integrated circuit 100 may have a logic low level.

While the scan enable signal (SEN) applied to the integrated circuit 100 has a logic high level, a shift-out operation may be performed (e.g., indicated as SHIFT-OUT) in which the observation values stored in the scan chain circuit 130 are sequentially output through the scan test output terminal (SOP) of the integrated circuit 100.

The scan flip-flops in the scan chain circuit 130 may operate in synchronization with the clock signal (CK) (e.g., triggered at the rising edge of the clock signal (CK). As an example embodiment, a plurality of scan input data (SI) may be used. A shift-out operation in which observation values for one scan input data (SI) is output and a shift-in operation in which the next scan input data (SI) is input may be performed simultaneously.

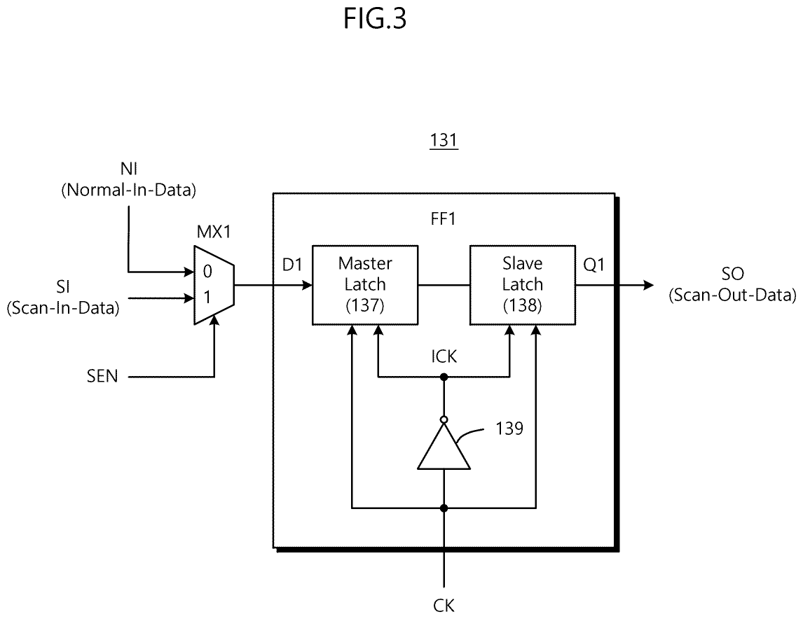

FIG. 3 is a block diagram illustrating an example embodiment of the first scan flip-flop of the scan chain circuit illustrated in FIG. 1. Referring to FIG. 3, the first scan flip-flop 131 may include a first multiplexer (MX1) and a first flip-flop (FF1). The first flip-flop (FF1) may include a master latch 137, a slave latch 138, and a clock inverter 139.

When the scan enable signal (SEN) has a logic high level, the first scan flip-flop 131 may output scan input data (SI) as scan output data (SO) through the master latch 137 and the slave latch 138. When the scan enable signal (SEN) has a logic low level, the normal input data (NI) may be output as an output signal (Q1) through the master latch 137 and the slave latch 138. Therefore, the first scan flip-flop 131 may be selectively operated in a normal mode or a scan mode by a scan enable signal (SEN) applied to the first multiplexer (MX1).

The first scan flip-flop 131 may receive a clock signal (CK) to operate the first flip-flop (e.g., FF1). The first flip-flop (FF1) may receive the clock signal (CK) and include a clock inverter 139 for providing an inverted clock signal (ICK). The first scan flip-flop 131 may be triggered at the rising edge of the clock signal (CK), e.g., the falling edge of the inverted clock signal (ICK).

As an example embodiment, among the scan flip-flops included in the scan chain circuit 130, the first scan flip-flop 131 may include a first multiplexer (MX1) and a first flip-flop (FF1), and the second scan flip-flop 132 also may include a second multiplexer (MX2) and a second flip-flop (FF2), respectively. The first flip-flop (FF1) and the second flip-flop (FF2) may have different structures from each other. In addition, the first multiplexer (MX1) and the second multiplexer (MX2) may have different structures from each other.

As an example embodiment, the integrated circuit 100 may further include a multiplexer for using one of the main input terminals (PI) as a scan test input terminal (SIP) while the scan test is performed, or a multiplexer for using one of the main output terminals (PO) as a scan test output terminal (SOP) while the scan test is performed. However, this is an example, and the scan test input terminal (SIP) and the scan test output terminal (SOP) within the integrated circuit 100 may be used in various ways.

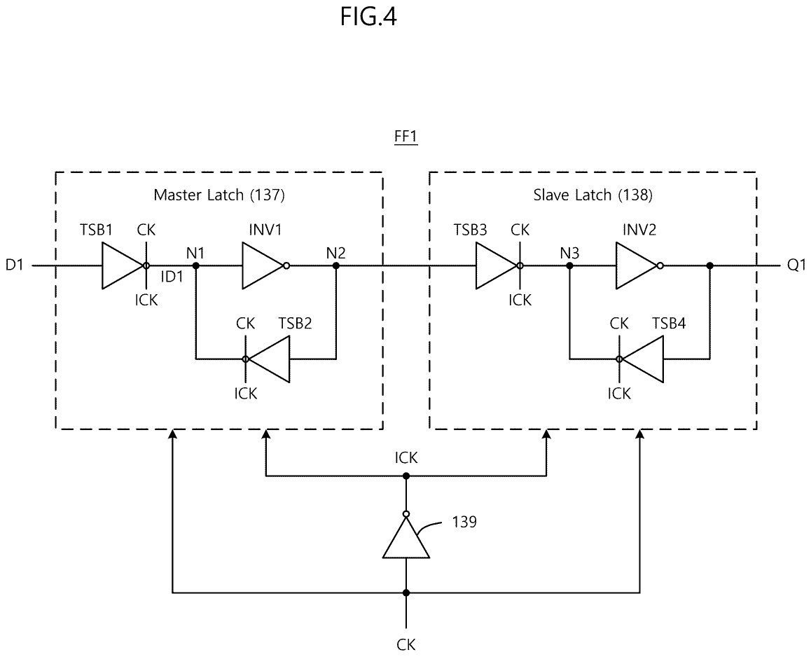

FIG. 4 is a circuit diagram illustrating an example embodiment of the first flip-flop illustrated in FIG. 3. Referring to FIG. 4, the first Flip-flop (FF1) may include a master latch 137, a slave latch 138, and a clock inverter 139.

The master latch 137 may include a first three-phase buffer (TSB1), a first inverter (INV1), and a second three-phase buffer (TSB2). The first three-phase buffer (TSB1) may be connected to a first signal input terminal to which a first input signal (D1) is applied. That is, the first three-phase buffer (TSB1) may be connected between the first signal input terminal and the first inverter (INV1).

When the clock signal (CK) has a logic low level and the inverted clock signal (ICK) has a logic high level, the first three-phase buffer (TSB1) may invert the first input signal (D1) and output the first inverted input signal (ID1) to the first node (N1). When the clock signal (CK) has a logic high level and the inverted clock signal (ICK) has a logic low level, the first three-phase buffer (TSB1) may block the first inverter (INV1) from the first signal input terminal.

The first inverter (INV1) may be connected to the output terminal of the first three-phase buffer (TSB1). That is, the first inverter (INV1) may be connected between the first three-phase buffer (TSB1) and the second node (N2). The first inverter (INV1) may invert the first inverted input signal (ID1) received from the first three-phase buffer (TSB1) and output the first input signal (D1) to the second node (N2).

The second three-phase buffer (TSB2) may be connected between the output terminal of the first inverter (INV1) and the output terminal of the first three-phase buffer (TSB1). When the clock signal (CK) has a logic high level and the inverted clock signal (ICK) has a logic low level, the second three-phase buffer (TSB2) may invert the first input signal (D1) received from the first inverter (INV1) and output the first inverted input signal (ID1). When the clock signal (CK) has a logic low level and the inverted clock signal (ICK) has a logic high level, the second three-phase buffer (TSB2) may block the output terminal of the second three-phase buffer (TSB2) from the output terminal of the first inverter (INV1).

The slave latch 138 may include a third three-phase buffer (TSB3), a second inverter (INV2), and a fourth three-phase buffer (TSB4). The third three-phase buffer (TSB3) may be connected between the second node (N2) and the third node (N3). That is, the third three-phase buffer (TSB3) may be connected between the output terminal of the master latch 137 and the second inverter (INV2).

When the clock signal (CK) has a logic low level and the inverted clock signal (ICK) has a logic high level, the third three-phase buffer (TSB3) may invert the signal of the second node (N2) and output it to the third node (N3). When the clock signal (CK) has a logic high level and the inverted clock signal (ICK) has a logic low level, the third three-phase buffer (TSB3) may block the second inverter (INV2) from the second node (N2).

The second inverter (INV2) may be connected to the output terminal of the third three-phase buffer (TSB3). That is, the second inverter (INV2) may be connected between the third three-phase buffer (TSB3) and the output terminal (Q1). The second inverter (INV2) may output the signal received from the third three-phase buffer (TSB3) to the output terminal (Q1).

The fourth three-phase buffer (TSB4) may be connected between the output terminal of the second inverter (INV2) and the output terminal of the third three-phase buffer (TSB3). When the clock signal (CK) has a logic high level and the inverted clock signal (ICK) has a logic low level, the fourth three-phase buffer (TSB4) may invert and output the signal received from the second inverter (INV2). When the clock signal (CK) has a logic low level and the inverted clock signal (ICK) has a logic high level, the fourth three-phase buffer (TSB4) may block the output terminal of the fourth three-phase buffer (TSB4) from the output terminal of the second inverter (INV2).

The clock inverter 139 may receive a clock signal (CK) from the scan controller 120 and generate an inverted clock signal (ICK). The inverted clock signal (ICK) may be provided to the master latch 137 and the slave latch 138.

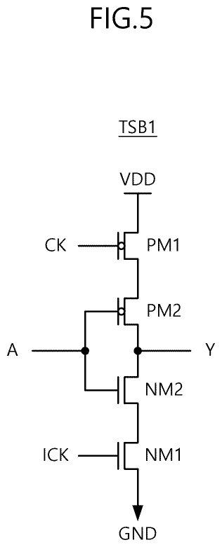

FIG. 5 is a circuit diagram illustrating an example embodiment of the first three-phase buffer illustrated in FIG. 4. Referring to FIG. 5, the first three-phase buffer (TSB1) may be controlled by the clock signal (CK) and the inverted clock signal (ICK).

When the clock signal (CK) has a logic low level and the inverted clock signal (ICK) has a logic high level, the first three-phase buffer (TSB1) may invert the input signal (A) and provide it as an output signal (Y). When the clock signal (CK) has a logic high level and the inverted clock signal (ICK) has a logic low level, the first three-phase buffer (TSB1) may not perform an operation of inverting the input signal (A) and outputting the output signal (Y).

The first three-phase buffer (TSB1) may include a first p-channel metal-oxide semiconductor (PMOS) transistor (PM1), a second PMOS transistor (PM2), a first n-channel metal-oxide semiconductor (NMOS) transistor (NM1), and a second NMOS transistor (NM2).

The first PMOS transistor (PM1) may be connected between a power terminal (VDD) and the second PMOS transistor (PM2). The gate terminal of the first PMOS transistor (PM1) may receive the clock signal (CK). The second PMOS transistor (PM2) may be connected between the first PMOS transistor (PM1) and the second NMOS transistor (NM2). The gate terminal of the second PMOS transistor (PM2) may receive an input signal (A).

The first NMOS transistor (NM1) may be connected between a ground terminal (GND) and the second NMOS transistor (NM2). The gate terminal of the first NMOS transistor (NM1) may receive an inverted clock signal (ICK). The second NMOS transistor (NM2) may be connected between the first NMOS transistor (NM1) and the second PMOS transistor (PM2). The gate terminal of the second NMOS transistor (NM2) may receive an input signal (A).

The connection node where one terminal of the second PMOS transistor (PM2) and one terminal of the second NMOS transistor (NM2) are connected may correspond to an output node, and an output signal (Y) may be output through the output node.

When the clock signal (CK) has a logic low level and the inverted clock signal (ICK) has a logic high level, the first PMOS transistor (PM1) and the first NMOS transistor (NM1) may be turned on. When the input signal (A) has a logic high level, the second NMOS transistor (NM2) may be turned on to output an output signal (Y) having a logic low level. When the input signal (A) has a logic low level, the second PMOS transistor (PM2) may be turned on to output an output signal (Y) having a logic high level. The first three-phase buffer (TSB1) illustrated in FIG. 5 is only one example, and the first three-phase buffer (TSB1) included in the first flip-flop (FF1) is not limited in this regard.

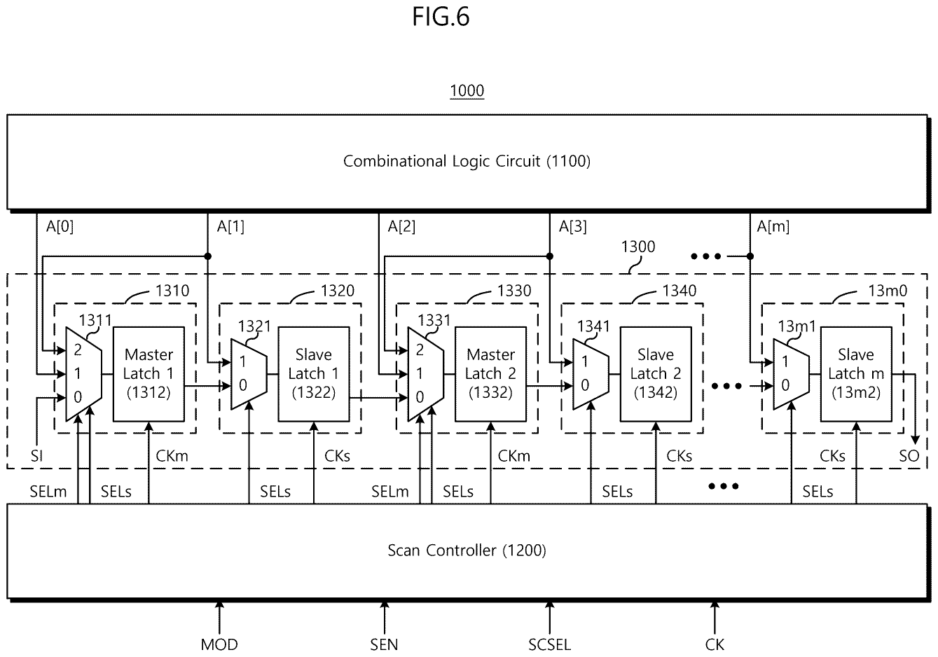

FIGS. 6 to 8 are block diagrams illustrating a semiconductor integrated circuit having a scan chain circuit according to an embodiment of the present disclosure. Referring to FIG. 6, the semiconductor integrated circuit 1000 may include a combinational logic circuit 1100, a scan controller 1200, and a scan chain circuit 1300. The scan chain circuit 1300 may include a plurality of scan latches 1310 to 13m0.

The first scan latch 1310 may include a first master multiplexer 1311 and a first master latch 1312. The second scan latch 1320 may include a first slave multiplexer 1321 and a first slave latch 1322. The third scan latch 1330 may include a second master multiplexer 1331 and a second master latch 1332. The fourth scan latch 1340 may include a second slave multiplexer 1341 and a second slave latch 1342. And the m-th scan latch 13m0 may include a slave multiplexer 1341 and a slave latch 13m2.

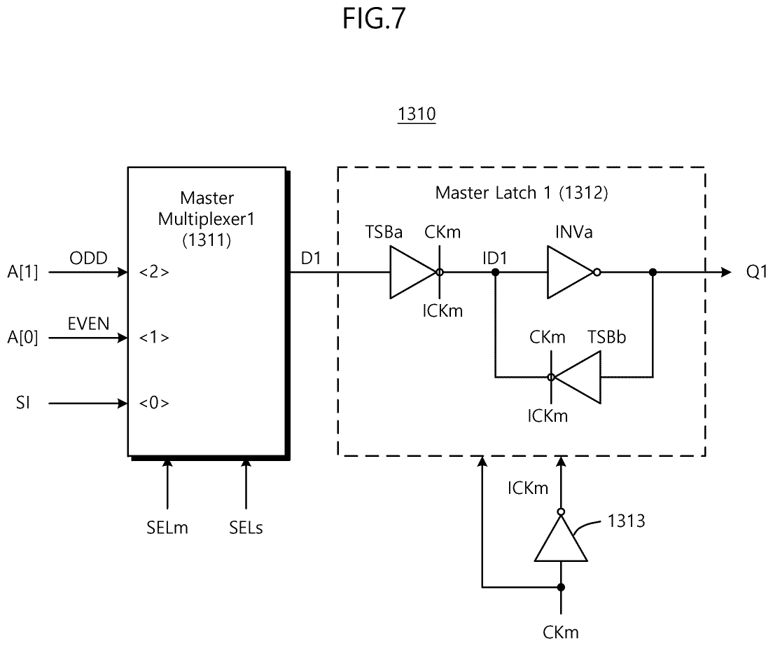

Referring to FIG. 7, the first scan latch 1310 may include a first master multiplexer 1311, a first master latch 1312, and a clock inverter 1313. The first master multiplexer 1311 may be a 3×1 multiplexer having three input terminals and one output terminal. For example, the first input terminal <0> may receive scan input data, the second input terminal <1> may receive an even signal (EVEN), and the third input terminal <2> may receive an odd signal (ODD). The even signal (EVEN) may be A[0], and the odd signal (ODD) may be A[1]. A[0] and A[1] may be provided from the combinational logic circuit 1100.

The first master multiplexer 1311 may receive a master selection signal (SELm) and a slave selection signal (SELs) from the scan controller 1200, and may connect any one of the three input terminals to an output terminal. For example, if the master selection signal (SELm) is a logic low level (L) and the slave selection signal (SELs) is a logic low level (L), the second input terminal <1> is selected, and the even signal A[0] may be provided as an output terminal. If the master selection signal (SELm) is a logic high level (H) and the slave selection signal (SELs) is a logic low level (L), the third input terminal <2> is selected, and the odd signal A[1] may be provided as an output terminal.

The first master latch 1312 may include a first three-phase buffer (TSBa), a first inverter (INVa), and a second three-phase buffer (TSBb). The first three-phase buffer (TSBa) may be connected between the first signal input terminal and the first inverter (INVa). The first inverter (INVa) may be connected between the first three-phase buffer (TSBa) and the output terminal. The first inverter (INVa) may invert and output an inverted input signal (ID1) received from the first three-phase buffer (TSBa). The second three-phase buffer (TSBb) may be connected between the output terminal of the first inverter (INVa) and the output terminal of the first three-phase buffer (TSBa).

The clock inverter 1313 may receive the master clock signal (CKm) from the scan controller 1200 and generate the inverted master clock signal (ICKm). The master clock signal (CKm) and the inverted master clock signal (ICKm) may be provided to the first master latch 1312.

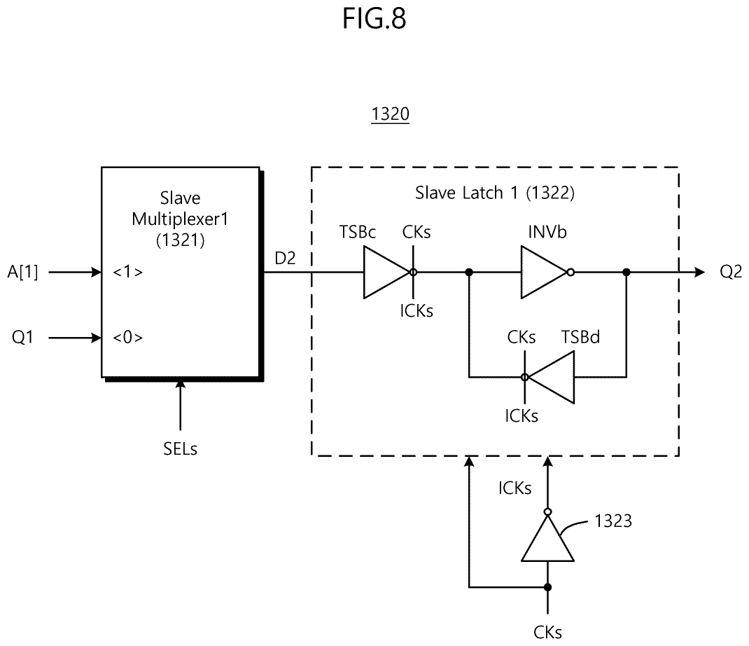

Referring to FIG. 8, the second scan latch 1320 may include a first slave multiplexer 1321, a first slave latch 1322, and a clock inverter 1323. The first slave multiplexer 1321 may be a 2×1 multiplexer having two input terminals and one output terminal. For example, the first input terminal <0> may receive an output signal of the first scan latch 1310, and the second input terminal <1> may receive an odd signal (ODD). The odd signal (ODD) may be A[1]. A[1] may be provided from the combinational logic circuit 1100.

The first slave multiplexer 1321 may receive a slave selection signal (SELs) from the scan controller 1200, and may connect one of the two input terminals to the output terminal. For example, if the slave selection signal (SELs) is a logic low level (L), the first input terminal <0> may be selected, and if the slave selection signal (SELs) is a logic high level (H), the first input terminal <1> may be selected.

The first slave latch 1322 may include a third three-phase buffer (TSBc), a second inverter (INVb), and a fourth three-phase buffer (TSBd). The third three-phase buffer (TSBc) may be connected between a second signal input terminal and the second inverter (INVb). The second inverter (INVb) may be connected between the third three-phase buffer (TSBc) and an output terminal. The fourth three-phase buffer (TSBd) may be connected between the output terminal of the second inverter (INVb) and the output terminal of the third three-phase buffer (TSBc).

The clock inverter 1323 may receive a clock signal (CKs) from the scan controller 1200 and generate an inverted slave clock signal (ICKs). The slave clock signal (CKs) and the inverted slave clock signal (ICKs) may be provided to the first slave latch 1312.

Referring again to FIG. 6, the scan controller 1200 may receive a scan enable signal (SEN), a scan mode signal (MOD), a scan select signal (SCSEL), and a clock signal (CK). The scan controller 1200 may receive a scan mode signal (MOD) and perform a scan test operation. For example, if the scan mode signal (MOD) is a logic low level (L), it may operate in a normal mode. And if the scan mode signal (MOD) is a logic high level (H), it may operate in a scan mode.

The scan controller 1200 may receive a scan enable signal (SEN) and/or a scan select signal (SCSEL), and provide a first selection signal (SELm) and/or a second selection signal (SELs) to the scan chain circuit 1300. For example, the first selection signal (SELm) may be provided to the master multiplexers 1311, 1331, etc. And the second selection signal (SELs) may be provided to all the multiplexers. The scan enable signal (SEN) may be disabled in normal mode and enabled in scan mode. The scan select signal (SCSEL) may be used to select an even signal (EVEN) or an odd signal (ODD).

The scan controller 1200 may receive a clock signal (CK) and generate a master clock signal (CKm) and a slave clock signal (CKs). The scan controller 1200 may provide the master clock signal (CKm) to master latches (e.g., 1312, 1332, etc.) and provide the slave clock signal (CKs) to slave latches (e.g., 1322, 1324, etc.).

The scan controller 1200 may perform a scan test operation. The scan test operation may be performed by performing a shift-in operation in which scan input data (SI) is sequentially loaded into the scan chain circuit 1300, a capture operation in which the observation values of the combinational logic circuit 110 are stored in the scan chain circuit 1300 in synchronization with the loaded scan input data (SI), and a shift-out operation in which the observation values stored in the scan chain circuit 1300 are sequentially output as scan output data (SO).

The scan chain circuit 1300 of the semiconductor integrated circuit 1000 illustrated in FIG. 6 may include a plurality of scan latches 1310 to 13m0. Each scan latch may include multiplexers and latches. As an example embodiment of the present disclosure, the semiconductor integrated circuit 1000 may reduce the area of the scan chain circuit 1300 by using a latch instead of a flip-flop in each scan latch. Hereinafter, the normal operation and the scan test operation of the semiconductor integrated circuit 1000 will be described.

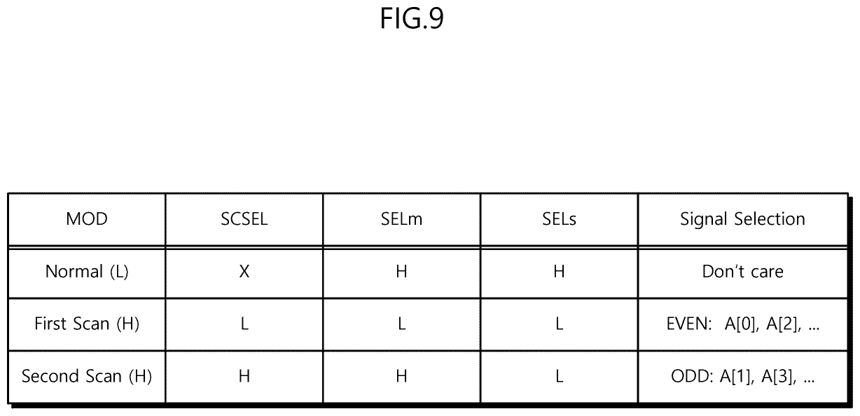

FIG. 9 is a table illustrating an example embodiment of the mode operation of the semiconductor integrated circuit illustrated in FIG. 6. Referring to FIG. 9, when the mode signal (MOD) is a logic low level (L), the normal mode may be performed.

The normal mode may be performed regardless of the scan selection signal (SCSEL; X), when the first selection signal (SELm) is a logic high level (H) and the second selection signal (SELs) is a logic high level (H). When the mode signal (MOD) is a logic high level (H), the scan operation may be performed. The scan mode may be divided into the first and second scan modes according to the scan selection signal (SCSEL).

The first scan mode is performed when the scan selection signal (SCSEL) is a logic low level (L), and even signals (EVEN) may be selected. Even signals (EVEN) may be provided from the combinational logic circuit 1100 as A[0], A[2], etc. The master multiplexers may receive first and second selection signals (SELm, SELs) and connect even signals (EVEN) to the master latches. For example, when the first selection signal (SELm) is a logic low level (L) and the second selection signal (SELs) is a logic low level (L), the even signals (EVEN) may be connected to the master latches.

The second scan mode is performed when the scan selection signal (SCSEL) is a logic high level (H), and the odd signals (ODD) may be selected. The odd signals (ODD) may be provided from the combinational logic circuit 1100 as A[1], A[3], etc. The master multiplexers may receive first and second selection signals (SELm, SELs) and connect the odd signals (ODD) to the master latches. For example, when the first selection signal (SELm) is at a logic high level (H) and the second selection signal (SELs) is at a logic low level (L), the odd signals (ODD) may be connected to the master latches.

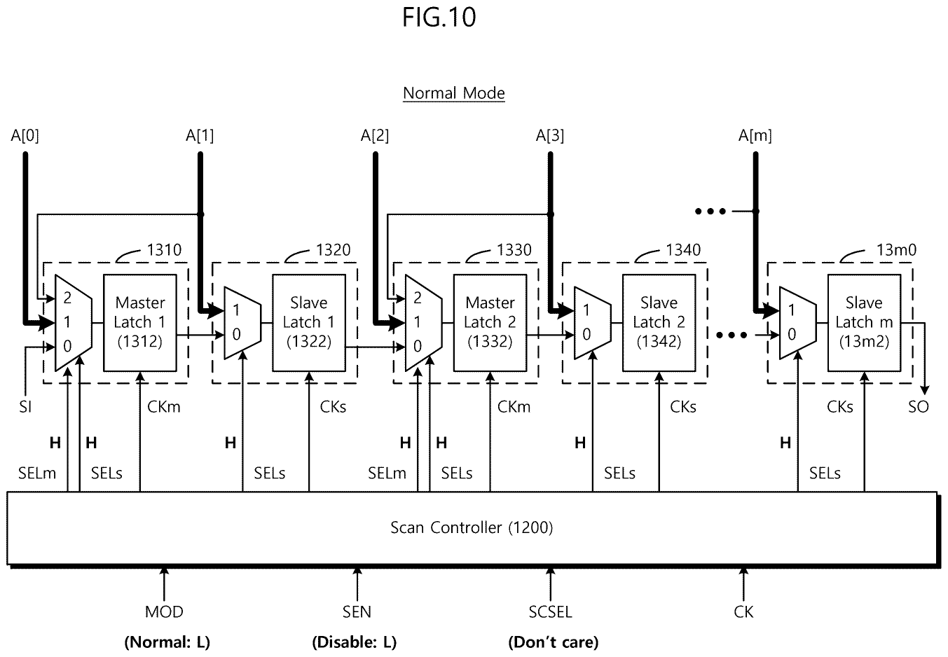

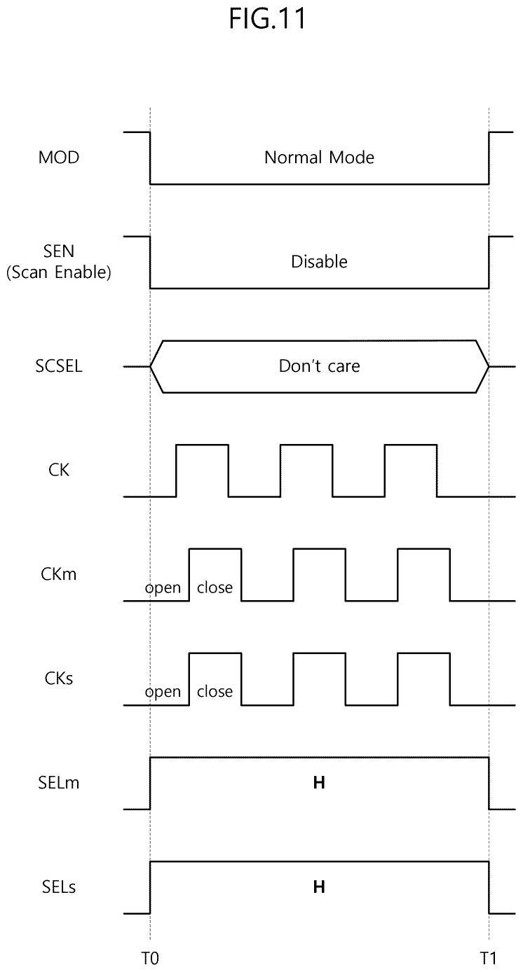

FIGS. 10 and 11 are circuit diagrams and timing diagrams illustrating an example embodiment of the normal mode of the semiconductor integrated circuit illustrated in FIG. 6. Referring to FIGS. 10 and 11, the normal mode may be performed when the mode signal (MOD) is at a logic low level (L) during the time period T0 to T1. In the normal mode, the scan enable signal (SEN) may be disabled to a logic low level (L). The normal mode may be performed when both the first selection signal (SELm) and the second selection signal (SELs) are at a logic high level (H), regardless of the scan selection signal (SCSEL).

During the normal mode, master latches (such as 1312, 1332) and slave latches (such as 1322, 1342, 13m2) may perform open and close operations simultaneously in synchronization with the master clock signal (CKm) and the slave clock signal (CKs) to receive signals (A[0], A[1], A[2], . . . , A[m]) from the combinational logic circuit 1100.

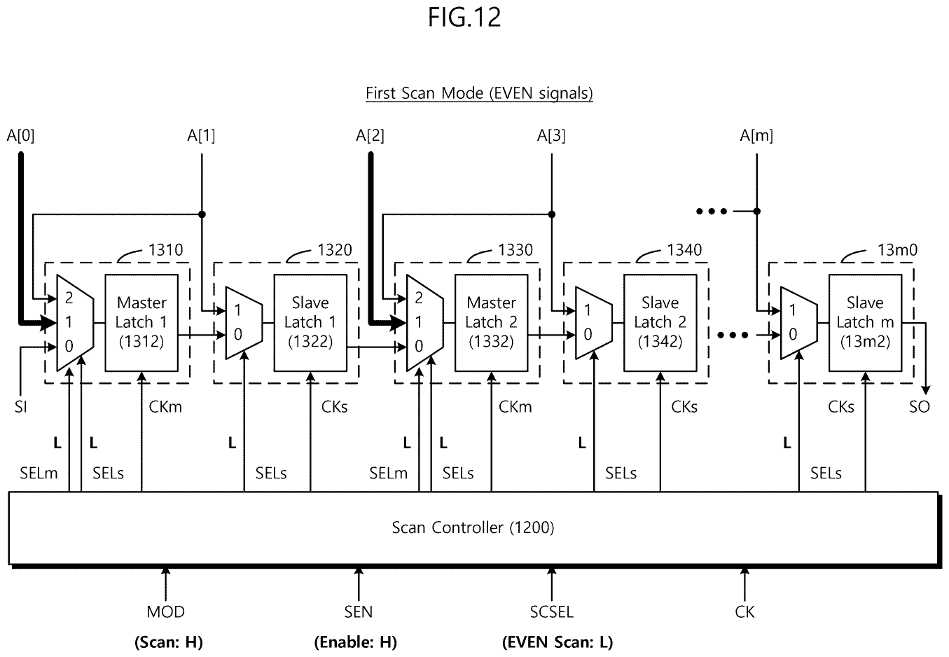

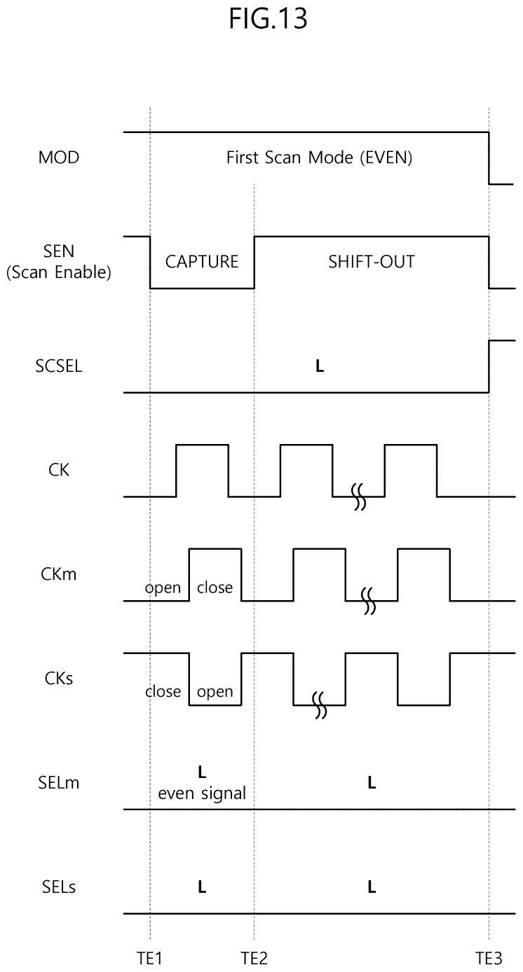

FIGS. 12 and 13 are circuit diagrams and timing diagrams illustrating an example embodiment of a first scan mode of the semiconductor integrated circuit illustrated in FIG. 6. The semiconductor integrated circuit 1000 may perform a shift-in operation, a capture operation, and a shift-out operation.

Referring to FIGS. 12 and 13, the capture operation of the first scan mode may be performed during the TE1 to TE2 time interval. The first scan mode may receive even signals (EVEN) from the combinational logic circuit 1100 during the capture operation.

The first scan mode may be performed when the mode signal (MOD) is a logic high level (H). The scan enable signal (SEN) of the first scan mode may be a logic low level (L) during the capture operation time interval (TE1 to TE2) and a logic high level (H) during the shift-out operation time interval (TE2 to TE3). During the first scan mode, the scan selection signal (SCSEL) may be a logic low level (L). The scan selection signal (SCSEL) of the low level may be used to select the even signals (EVEN).

During the first scan mode, the master clock signal (CKm) and the slave clock signal (CKs) may operate in opposite phases. For example, when the master clock signal (CKm) is in a closed state, the slave clock signal (CKs) may be in an open state. The master latches (1312, 1332, etc.) may receive even signals (A[0], A[2], etc.) from the combinational logic circuit 1100 in synchronization with the master clock signal (CKm) and the slave clock signal (CKs) and perform the capture operation. At this time, the first selection signal (SELm) may be a logic low level (L) and the second selection signal (SELs) may be a logic low level (L).

The semiconductor integrated circuit 1000 may perform a shift-out operation while maintaining the scan selection signal (SCSEL) at a logic low level (L) during the shift-out operation time interval (TE2~TE3).

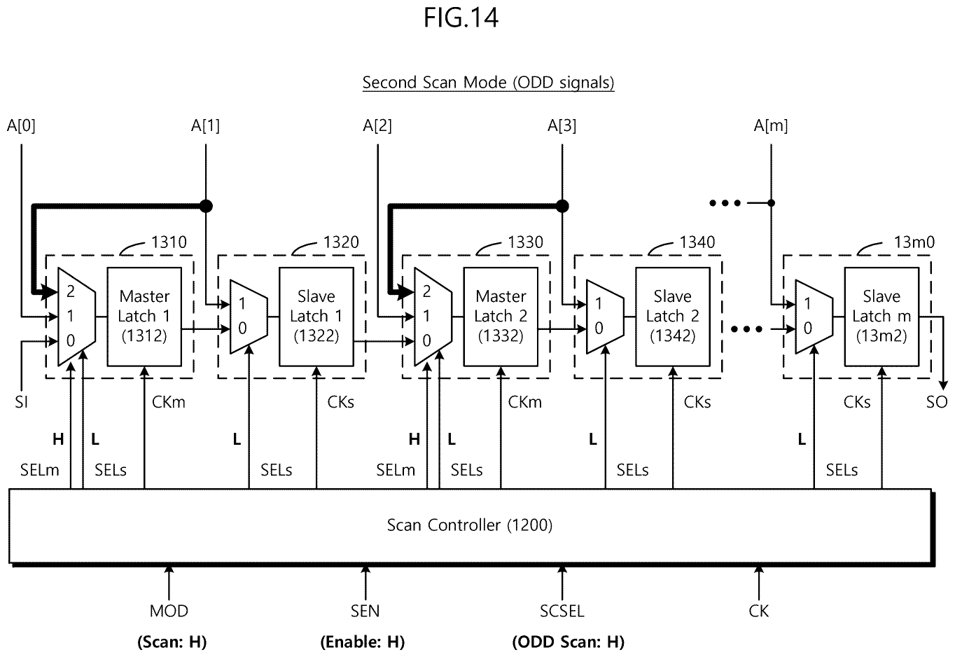

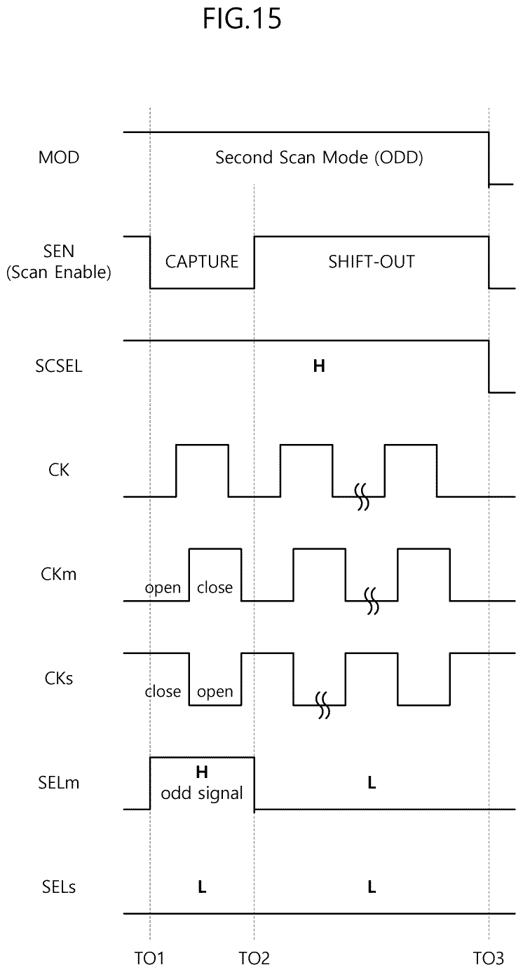

FIGS. 14 and 15 are circuit diagrams and timing diagrams illustrating an example embodiment of the second scan mode of the semiconductor integrated circuit illustrated in FIG. 6. The semiconductor integrated circuit 1000 may perform a shift-in operation, a capture operation, and a shift-out operation.

Referring to FIGS. 14 and 15, the capture operation of the second scan mode may be performed during the TO1 to TO2 time interval. The second scan mode may receive odd signals (ODD) from the combinational logic circuit 1100 during the capture operation.

The second scan mode may be performed when the mode signal (MOD) is a logic high level (H). The scan enable signal (SEN) of the second scan mode may be a logic low level (L) during the capture operation time interval (TO1~TO2) and a logic high level (H) in the shift-out operation period (TO2~TO3). During the second scan mode, the scan selection signal (SCSEL) may be a logic high level (H). The scan selection signal (SCSEL) of high level may be used to select the odd signals (ODD).

During the second scan mode, the master clock signal (CKm) and the slave clock signal (CKs) may operate in opposite phases. For example, if the master clock signal (CKm) is in a closed state, the slave clock signal (CKs) may be in an open state. The master latches (1312, 1332, etc.) may receive the odd signals (A[1], A[3], . . . , A[m]) from the combinational logic circuit 1100 in synchronization with the master clock signal (CKm) and the slave clock signal (CKs) and perform the capture operation. At this time, the first selection signal (SELm) may be a logic high level (H), and the second selection signal (SELs) may be a logic low level (L).

The semiconductor integrated circuit 1000 may perform a shift-out operation while maintaining the scan selection signal (SCSEL) at a logic high level (H) during the shift-out operation time interval (TO2 to TO3).

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A scan chain circuit of a semiconductor integrated circuit, comprising:
a first scan latch configured to receive a first signal from a combinational logic circuit during a first scan operation and store the first signal in a master latch in response to a first clock signal, and receive a second signal from the combinational logic circuit during a second scan operation and store the second signal in the master latch in response to the first clock signal; and
a second scan latch configured to form a scan chain with the first scan latch, and store a signal provided from the combinational logic circuit in a slave latch in response to a second clock signal.

2. The scan chain circuit of claim 1, wherein the first scan latch includes a master multiplexer, and
wherein the master multiplexer includes:
a first input terminal configured to receive scan input data;
a second input terminal configured to receive the first signal from the combinational logic circuit; and
a third input terminal configured to receive the second signal from the combinational logic circuit.

3. The scan chain circuit of claim 2, wherein the master multiplexer provides one of the first and second signals to the master latch through an output terminal in response to a first selection signal and a second selection signal.

4. The scan chain circuit of claim 3, wherein the master latch has a single latch.

5. The scan chain circuit of claim 3, wherein the master latch includes:
a first three-phase buffer configured to operate in response to the first clock signal and an inverted first clock signal;
a first inverter connected between the first three-phase buffer and an output terminal; and
a second three-phase buffer connected between the output terminal of the first inverter and the output terminal of the first three-phase buffer, and
wherein the first inverter and the second three-phase buffer are configured as a latch.

6. The scan chain circuit of claim 3, wherein the second scan latch includes a slave multiplexer, and
wherein the slave multiplexer includes:
a first input terminal configured to receive output data of the first scan latch; and
a second input terminal configured to receive data from the combinational logic circuit.

7. The scan chain circuit of claim 6, wherein the slave multiplexer provides one of the data input to the first input terminal and the data input to the second input terminal to the slave latch through an output terminal in response to the second selection signal.

8. The scan chain circuit of claim 6, wherein the slave latch has a single latch.

9. The scan chain circuit of claim 1, wherein the first and second scan latches store data provided from the combinational logic circuit in response to the first clock signal and the second clock signal during a normal operation.

10. The scan chain circuit of claim 1, wherein the semiconductor integrated circuit selects the first signal during a first scan operation and selects the second signal during a second scan operation, using a scan selection signal.

11. A semiconductor integrated circuit comprising:
a combinational logic circuit configured to generate a first signal and a second signal;
a scan chain circuit configured to include a first scan latch that operates in response to a first clock signal and a second scan latch that operates in response to a second clock signal; and
a scan controller configured to provide the first clock signal and the second clock signal,
wherein the first scan latch receives the first signal from the combinational logic circuit during a first scan operation and stores it in a master latch in response to the first clock signal, and receives the second signal from the combinational logic circuit during a second scan operation and stores it in the master latch in response to the first clock signal, and
wherein the second scan latch forms a scan chain with the first scan latch and stores the first or second signal provided from the combinational logic circuit in a slave latch in response to the second clock signal.

12. The semiconductor integrated circuit of claim 11, wherein each of the master latch and the slave latch has a single latch.

13. The semiconductor integrated circuit of claim 11, wherein the first scan latch includes a master multiplexer, and
wherein the master multiplexer comprises:
a first input terminal configured to receive scan input data;
a second input terminal configured to receive the first signal from the combinational logic circuit; and
a third input terminal configured to receive the second signal from the combinational logic circuit.

14. The semiconductor integrated circuit of claim 13, wherein the second scan latch includes a slave multiplexer, and
wherein the slave multiplexer includes:
a first input terminal configured to receive output data of the first scan latch; and
a second input terminal configured to receive data from the combinational logic circuit.

15. The semiconductor integrated circuit of claim 11, wherein the scan controller selects the first signal during a first scan operation and selects the second signal during a second scan operation, using a scan selection signal.

16. A scan test operation method of a semiconductor integrated circuit which includes a combinational logic circuit generating a first signal and a second signal, a scan chain circuit including a first scan latch operating in response to a first clock signal and a second scan latch operating in response to a second clock signal, and a scan controller providing the first clock signal and the second clock signal,
the method comprising:
receiving the first signal from the combinational logic circuit during a first scan operation and storing it in a master latch in response to the first clock signal; and
receiving the second signal from the combinational logic circuit during a second scan operation and storing it in the master latch in response to the first clock signal.

17. The method of claim 16, wherein the second scan latch forms a scan chain with the first scan latch, and stores a signal provided from the combinational logic circuit in a slave latch in response to the second clock signal.

18. The method of claim 17, wherein each of the master latch and the slave latch has a single latch.

19. The method of claim 16, wherein the first signal is selected during the first scan operation and the second signal is selected during the second scan operation, using a scan select signal.

20. The method of claim 16, wherein the first scan latch further includes a master multiplexer having at least three input terminals.
